(19) United States
(12) Patent Application Publication
(10) Pub. No.: US 2013/0314890 A1
(43) Pub. Date: Nov. 28, 2013

(54) ELECTRONIC DISPLAY MOUNT WITH EXTREME TILT FEATURE

(71) Applicant: Paul Smith, Eden Prairie, MN (US)

(72) Inventor: Paul Smith, Eden Prairie, MN (US)

(73) Assignee: MILESTONE AV TECHNOLOGIES LLC, Eden Prairie, MN (US)

(21) Appl. No.: 13/990,750

(22) PCT Filed: Nov. 30, 2011
(86) PCT No.: PCT/US2011/062711

§ 371 Date: Aug. 9, 2013

Related U.S. Application Data
(60) Provisional application No. 61/418,377, filed on Nov. 30, 2010.

(51) Int. Cl. G06F 1/16; H05K 13/00

(52) U.S. Cl. CPC G06F 1/1601; H05K 13/00
USPC 361/825; 248/289.11; 29/428

(57) ABSTRACT

A display mount assembly, including a supporting member that engages to an environmental structure at a first end, a display interface coupled to a flat panel display device and a supporting member interface between the supporting member and the display interface. The supporting member interface includes an arcuate guide structure and a follower received therein. The arcuate guide structure subtends a first arcuate length, the ends of which limit arcuate travel of the follower. The follower structure defines a portion of the arcuate channel subtending a second arcuate length such that a difference between the first arcuate length and the second arcuate length is greater than or equal to about fifty degrees.

### CLAIM TO PRIORITY

The present application is a National Phase entry of PCT Application No. PCT/US2011/062711, filed Nov. 30, 2011, which application claims the benefit of U.S. Provisional Application Ser. No. 61/418,377 filed Nov. 30, 2010 and entitled “Electronic Display Mount with Extreme Tilt Feature” the entire contents of which are incorporated herein by reference.

### FIELD OF THE INVENTION

The present invention relates to electronic display devices such as flat panel electronic displays, and more specifically to mounting devices for flat panel electronic display devices.

### BACKGROUND OF THE INVENTION

Mounting devices for flat panel electronic display devices are known. For example, U.S. Pat. No. 6,905,101 and U.S. Pat. No. 7,152,836, both owned by the owners of the present invention and hereby incorporated herein by reference, disclose mounting devices for a flat panel electronic displays. Such a device has the drawback, however, of being capable of only a limited range of tilting motion due to the geometry of the device. It would be desirable, particularly in the case of a desk mounted display where the user may actually sit above the level of the display, for a mount to have the capability of tilting the display at a more extreme pitch angle relative to the vertical plane.

### SUMMARY OF THE INVENTION

The present invention addresses the need of the industry for an electronic display mount that enabled the display to be tilted at an extreme angle relative to the vertical plane.

A mount assembly according to an example embodiment of the invention generally includes a desk clamp, a lower arm, an upper arm assembly, and a tilt head assembly. The desk clamp generally includes an upper desk interface and an opposed lower clamp portion. The desk interface presents a lower surface which, in use, confronts an upwardly facing table or desk surface. A clamp portion engages the underside of the table or desk surface. An adjustment screw is operable to enable selective positioning of the clamp portion such that the desk clamp can engage around table or desk surfaces of varying thickness.

The lower arm is pivotally coupled to the desk clamp at a pivot. The upper arm assembly is pivotally coupled to the lower arm at another pivot such that the upper arm assembly and the lower arm combine to form an articulating arm assembly for enabling the tilt head assembly and an attached flat panel display device to be selectively positioned laterally side-to-side relative to the desk clamp. The upper arm assembly generally includes an upper arm body, a lower arm body, a gas spring, and a spring mount assembly. The upper arm assembly enables vertical positioning of the tilt head assembly and attached flat panel display device relative to the desk clamp and lower arm. The gas spring enables the display device to be stably positioned at any point in the vertical positioning range of the upper arm assembly without the need for another friction added mechanism. The arm assembly is presented as an example supporting structure and is not essential to the invention. The tilt head assembly of the invention can be used with other supporting structures that would benefit from an increased tilt range.

The tilt head assembly generally includes a display interface coupled to a support interface. The display interface generally includes a display interface flange and a guide structure. The display interface flange defines apertures and notches for receiving fasteners such as screws to fasten the tilt head assembly to the rear side of a display device. The guide structure may be integrally formed with the display interface flange, and generally includes a web portion and laterally extending flanges, such that the guide structure has a generally T-shaped cross-section. Stop structures project outwardly from the outer surface of flanges.

An example support interface generally includes a follower and a pivot post. The follower defines a channel conformingly shaped to slidingly receive the guide structure therein. The pivot post engages with the upper arm assembly to pivotally attach the tilt head assembly to the upper arm assembly.

It will be appreciated that the guide structure may define an arc of a circle with radius R. As the guide structure slides in the channel of the follower, the display interface and the attached display tilt about an axis A positioned in front of the display interface flange. Two stop structures engage the outer surfaces of the follower to define the upper and lower range limit respectively of the tilt position of the display interface. Preferably, the radius R is selected so that axis A is positioned proximate the center of gravity of the display, such that the display is self-balancing at any point along the range of tilt travel.

It will be appreciated that the tilt head assembly disclosed herein enables a more extreme range of tilt travel than mounts such as disclosed in U.S. Pat. No. 6,905,101 and U.S. Pat. No. 7,152,836. In embodiments of the invention as described herein, the tilt head assembly may enable a range of tilt travel from about 5 degrees down to about 45 degrees or even 60 degrees up, depending on the geometry of the guide structure and follower.

It is notable that the guide structure subtends a first arcuate length from end to end, in this example between the stops. The ends of the guide structure at the stops limit arcuate travel of the guide structure relative to the follower by abutting the follower. The follower defines the arcuate channel. The arcuate channel subtends a second arcuate length. The difference between the first arcuate length and the second arcuate length limits the range of arcuate travel of the guide structure relative to the follower.

In one example embodiment the arcuate range of travel is greater than or equal to about fifty degrees. In another example embodiment the arcuate range of travel is greater than or equal to about sixty degrees. In yet another example embodiment the arcuate range of travel is greater than or equal to about sixty five degrees.

### BRIEF DESCRIPTION OF THE DRAWINGS

FIG. 1 is a rear perspective view of a tilt head portion of an electronic display mount according to an embodiment of the invention;

FIG. 2 is a right side elevation view of the tilt head of FIG. 1;

FIG. 3 is a rear perspective view of the tilt head of FIG. 1 without the guide portion of the assembly;

FIG. 4 is a perspective view of a desk mounting arm assembly incorporating the tilt head of FIG. 1;

FIG. 5 is a cutaway perspective view of the upper portion of the arm assembly of FIG. 4 showing the gas spring positioning mechanism;

FIG. 6 is a top plan view of the arm assembly of FIG. 4;

FIG. 7 is a left side elevation view of the arm assembly of FIG. 4;

FIG. 8 is a right side elevation view of the arm assembly of FIG. 4;

FIG. 9 is a front elevation view of the arm assembly of FIG. 4;

FIG. 10 is a perspective exploded view of a tilt head assembly according to an example embodiment of the invention; and

FIG. 11 is a cross sectional view of a display interface and support interface according to an example embodiment of the invention.

### DETAILED DESCRIPTION

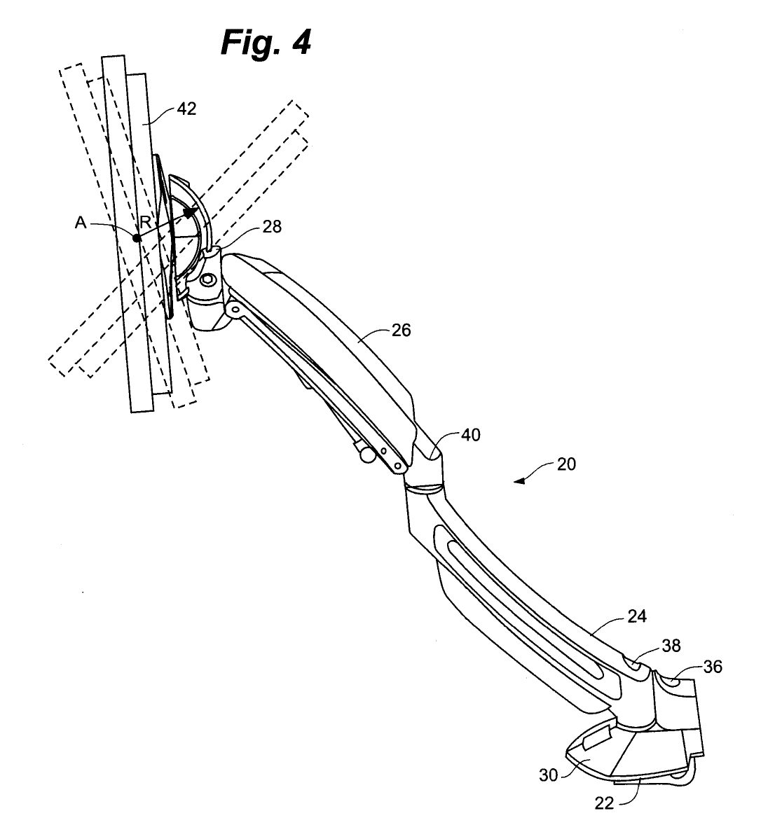

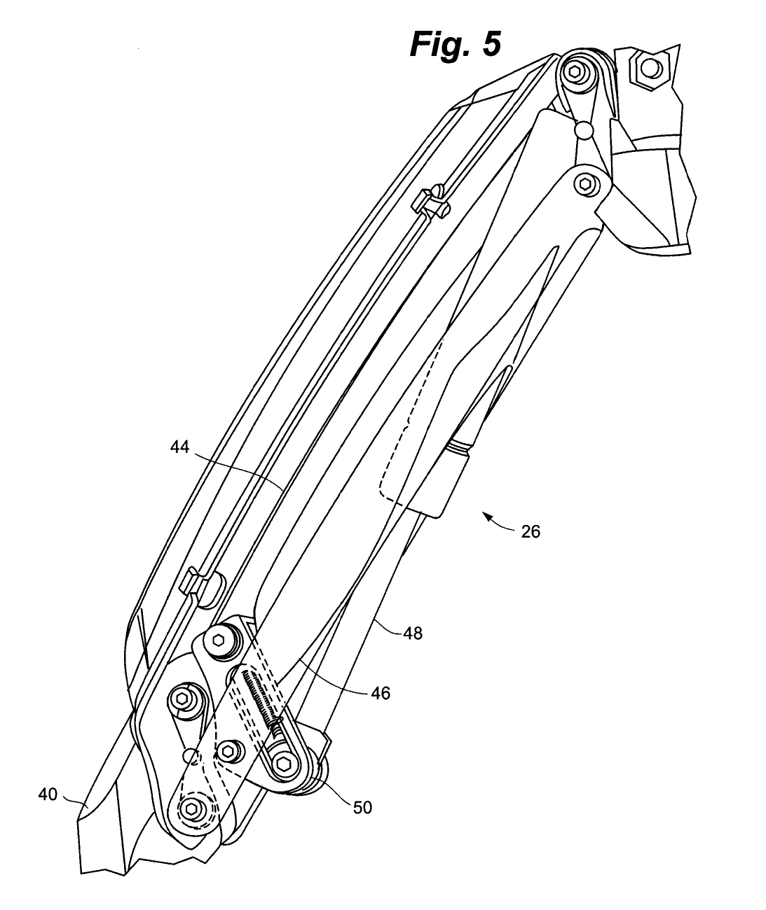

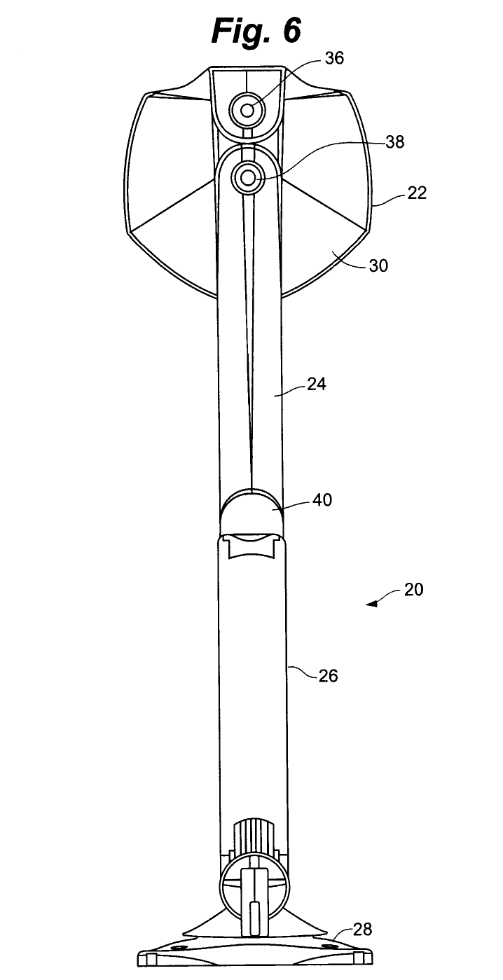

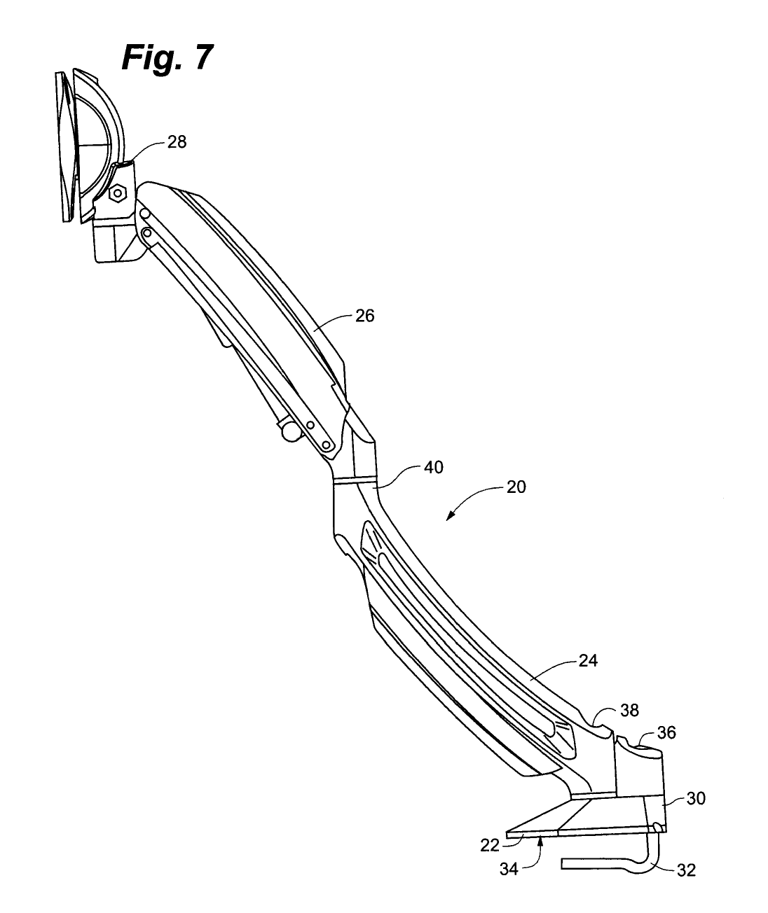

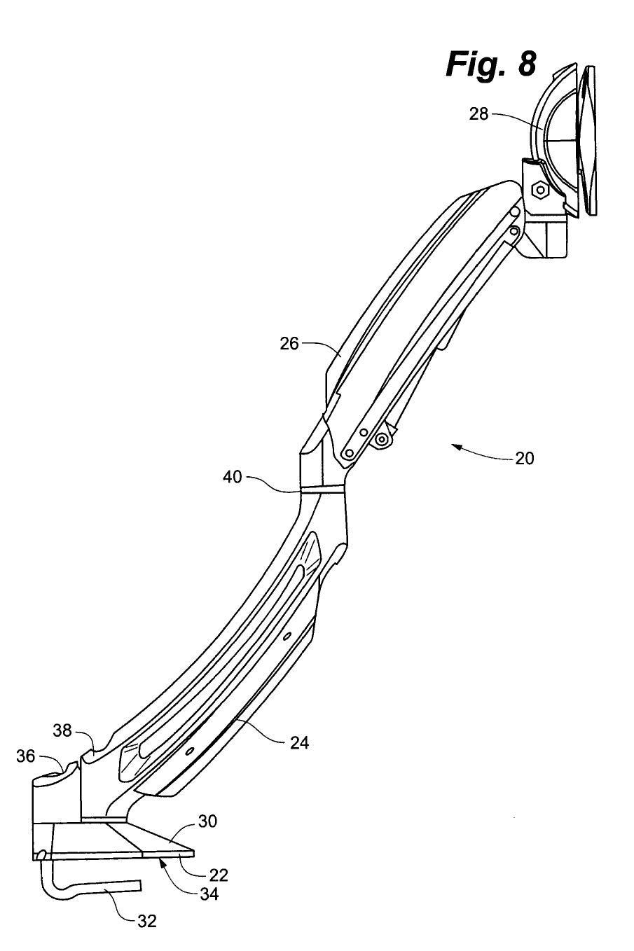

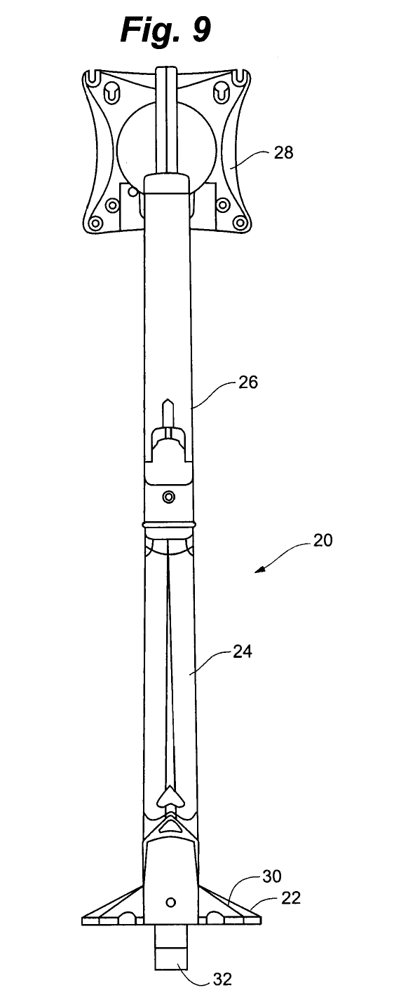

Mount assembly 20 as depicted in FIGS. 4-9 generally includes desk clamp 22, lower arm 24, upper arm assembly 26, and tilt head assembly 28. Desk clamp 22 generally includes upper desk interface 30 and lower clamp portion 32. Desk interface 30 presents lower surface 34 which, in use, confronts an upwardly facing table or desk surface (not shown). Clamp portion 32 engages the underside of the table or desk surface. Adjustment screw 36 is operable to enable selective positioning of clamp portion 32 such that desk clamp 22 can engage around table or desk surfaces of varying thickness.

Lower arm 24 is pivotally coupled to desk clamp 22 at pivot 38. Upper arm assembly 26 is pivotally coupled to lower arm 24 at pivot 40 such that upper arm assembly 26 and lower arm 24 combine to form an articulating arm assembly for enabling tilt head assembly 28 and an attached flat panel display device 42 to be selectively positioned laterally side-to-side relative to desk clamp 22. Upper arm assembly 26 generally includes upper arm body 44, lower arm body 46, gas spring 48, and spring mount assembly 50. Upper arm assembly 26 enables vertical positioning of tilt head assembly 28 and attached flat panel display device 42 relative to desk clamp 22 and lower arm 24. Gas spring 48 enables the display device 42 to be stably positioned at any point in the vertical positioning range of upper arm assembly 26 without the need for another friction added mechanism. Desk clamp 22, lower arm 24, upper arm assembly 26 are presented as an example supporting structure and are not essential to the invention. Tilt head assembly 28 of the invention can be used with other supporting structures that would benefit from an increased tilt range.

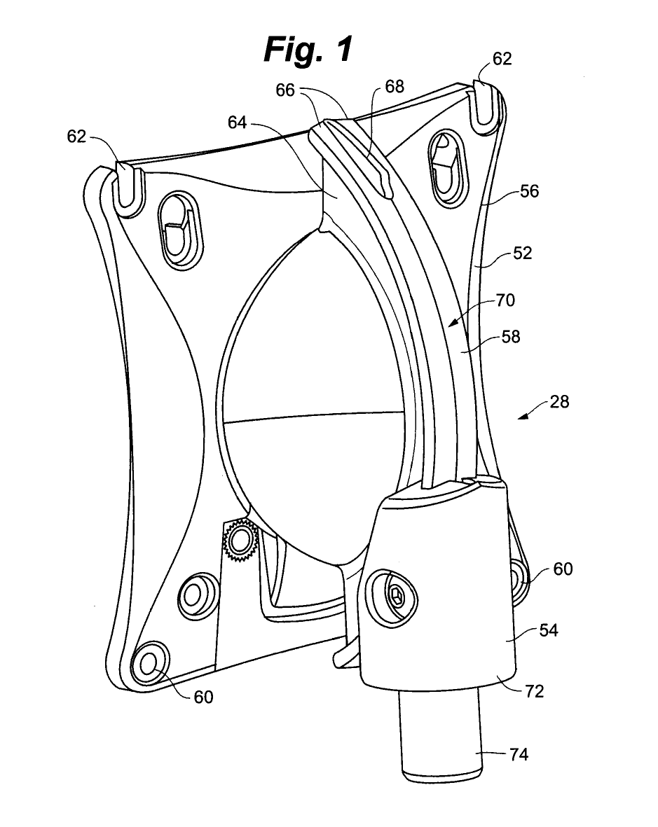

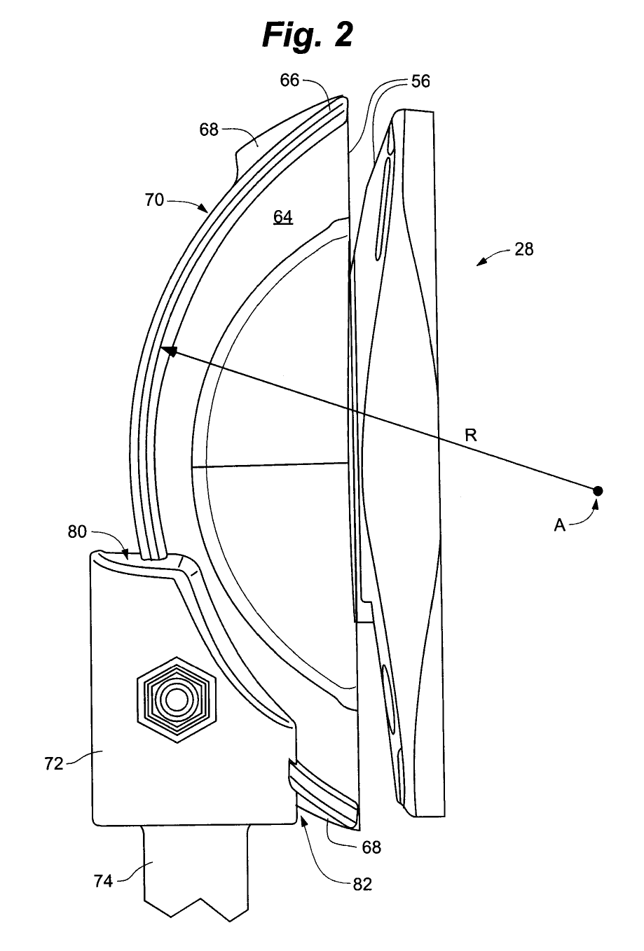

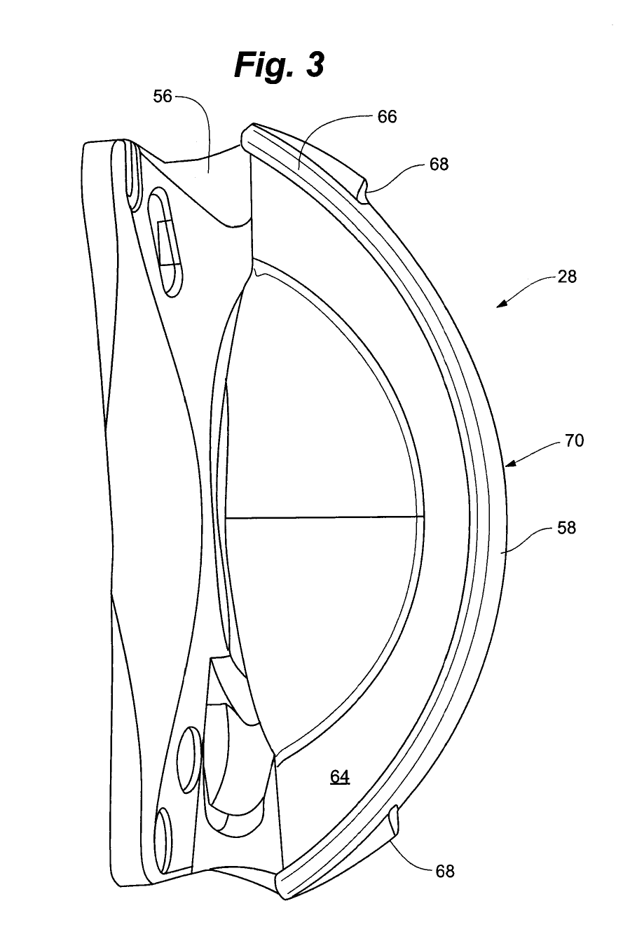

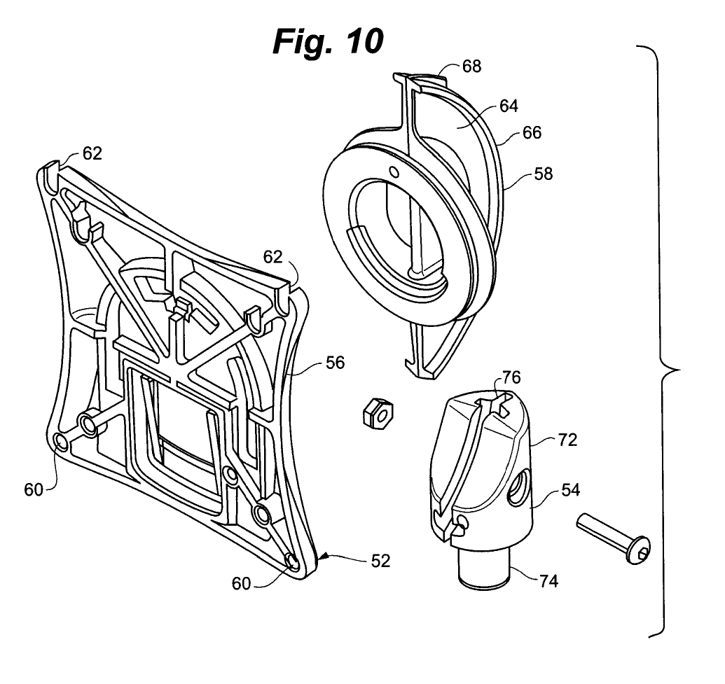

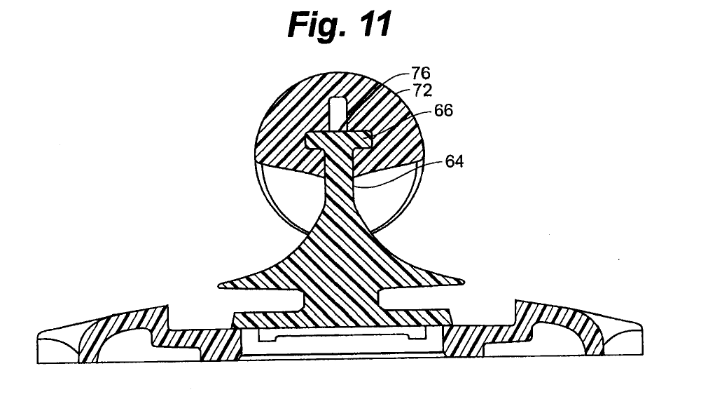

Tilt head assembly 28 as depicted in FIGS. 1-3 and 9-11 generally includes display interface 52 and support interface 54. Display interface 52 generally includes display interface flange 56 and guide structure 58. Display interface flange 56 defines apertures 60 and notches 62 for receiving fasteners (not shown) to fasten tilt head assembly 28 to the rear side of display device 42. Guide structure 58 may be integrally formed with display interface flange 56, and generally includes web portion 64 and laterally extending flanges 66, such that guide structure 58 has a generally T-shaped cross-section. Stop structures 68 project outwardly from outer surface 70 of flanges 66.

Support interface 54 generally includes follower 72 and pivot post 74. Follower 72 defines a channel conformingly shaped to slidingly receive guide structure 58 therein. Pivot post 74 engages with upper arm assembly 28 to pivotally attach tilt head assembly 28 to upper arm assembly 26.

It will be appreciated that guide structure 58 may define an arc of a circle with radius R. As guide structure 58 slides in the channel of follower 72, display interface 52 and the attached display 42 tilt about an axis A positioned in front of display interface flange 56. Stop structures 68 engage outer surfaces 80, 82, of follower 72 to define the upper and lower range respectively of the tilt position of display interface 52 Preferably, the radius R is selected so that axis A is positioned proximate the center of gravity of display 42, such that display 42 is self-balancing at any point along the range of tilt travel.

It will be appreciated that tilt head assembly 28 enables a more extreme range of tilt travel than mounts such as disclosed in U.S. Pat. Nos. 6,905,101 and 7,152,836. In embodiments of the invention as depicted in FIG. 4, tilt head assembly 28 may enable a range of tilt travel from about 5 degrees down to about 45 degrees or even 60 degrees up, depending on the geometry of guide structure 58 and follower 72.

The invention also includes a system including electronic flat panel display device 42 coupled to mount assembly 20 as described herein and a system including electronic flat panel display device 42 coupled to tilt head assembly 28 as described herein.

The present invention may be embodied in other specific forms without departing from the spirit of the essential attributes thereof; therefore, the illustrated embodiments should be considered in all respects as illustrative and not restrictive, reference being made to the appended claims rather than to the foregoing description to indicate the scope of the invention.

1. A display mount assembly, comprising:
a supporting member that engages to an environmental structure at a first end thereof;
a display interface that is couplable to a flat panel display device;
a supporting member interface interposed between a second end of the supporting member and the display interface, the supporting member interface including a guide structure and a follower;
the guide structure presenting a generally arcuate structure having a defined cross sectional shape;
the follower being engageable to the arcuate structure and defining an arcuate channel therethrough having a complementary shape to the defined cross sectional shape of the arcuate structure, the arcuate channel receiving the arcuate structure movably therein; and
the arcuate structure subtending a first arcuate length, the ends of which limit arcuate travel of the arcuate structure relative to the follower by abutting the follower and the follower defining the arcuate channel subtending a second arcuate length such that a difference between the first arcuate length and the second arcuate length is greater than or equal to about fifty degrees.

2. The mount assembly as claimed in claim 1, wherein the difference between the first arcuate length and the second arcuate length is greater than or equal to about sixty degrees.

3. The mount assembly as claimed in claim 1, wherein the difference between the first arcuate length and the second arcuate length is greater than or equal to about sixty five degrees.

4. The mount assembly as claimed in claim 1, wherein the arcuate structure comprises a flange extending from a web portion, the web portion and the arcuate flange defining the defined cross sectional shape.

4. The mount assembly as claimed in claim 1, further comprising a first stop structure at a first end of the arcuate structure and a second stop structure at a second end of the arcuate structure extending outwardly from the arcuate structure.

5. The mount assembly as claimed in claim 1, wherein the defined cross sectional shape is generally t-shaped.

6. The mount assembly as claimed in claim 1, wherein the arcuate structure and the arcuate channel each have a radius of curvature and the radius of curvature is selected such that a center of the radius is positioned on an opposing side of the display interface from the supporting member interface and spaced apart from the display interface.

7. A method of making a display mount assembly, comprising:
operably coupling a supporting member to a display interface that is couplable to a flat panel display device;
interposing a supporting member interface between the supporting member and the display interface;
structuring the supporting member interface to include a guide structure and a follower;
movably engaging a generally arcuate structure of the guide structure having a defined cross sectional shape to the follower at an arcuate channel passing therethrough having a complementary shape to the defined cross sectional shape of arcuate structure; and
structuring the arcuate structure to subtend a first arcuate length, the ends of which limit arcuate travel of the arcuate structure relative to the follower by abutting the follower; and
structuring a portion of the follower defining the arcuate channel to subtend a second arcuate length such that a difference between the first arcuate length and the second arcuate length is greater than or equal to about fifty degrees.

8. The method as claimed in claim 7, further comprising making the difference between the first arcuate length and the second arcuate length greater than or equal to about sixty degrees.

9. The method as claimed in claim 7, further comprising making the difference between the first arcuate length and the second arcuate length greater than or equal to about sixty five degrees.

10. The method as claimed in claim 7, further comprising making the arcuate structure include a flange extending from a web portion, the web portion and the arcuate flange defining the defined cross sectional shape.

11. The method as claimed in claim 7, further comprising forming a first stop structure at a first end of the arcuate structure and a second stop structure at a second end of the arcuate structure extending outwardly from the arcuate structure.

12. The method as claimed in claim 9, further comprising making the defined cross sectional shape generally t-shaped.

13. A display mount system, comprising:
an electronic flat panel display device;
a supporting member that engages to an environmental structure at a first end thereof;
a display interface that is coupled to the electronic flat panel display device;
a supporting member interface interposed between a second end of the supporting member and the display interface, the supporting member interface including a guide structure and a follower;
the guide structure presenting a generally arcuate structure having a defined cross sectional shape;
the follower being engageable to the arcuate structure and defining an arcuate channel therethrough having a complementary shape to the defined cross sectional shape of the arcuate structure, the arcuate channel receiving the arcuate structure movably therein; and
the arcuate structure subtending a first arcuate length, the ends of which limit arcuate travel of the arcuate structure relative to the follower by abutting the follower and the follower defining the arcuate channel subtending a second arcuate length such that a difference between the first arcuate length and the second arcuate length is greater than or equal to about fifty degrees.

14. The display mount system as claimed in claim 13, wherein the difference between the first arcuate length and the second arcuate length is greater than or equal to about sixty degrees.

15. The display mount system as claimed in claim 13, wherein the difference between the first arcuate length and the second arcuate length is greater than or equal to about sixty five degrees.

16. The display mount system as claimed in claim 13, wherein the arcuate structure comprises a flange extending from a web portion, the web portion and the arcuate flange defining the defined cross sectional shape.

17. The display mount system as claimed in claim 13, further comprising a first stop structure at a first end of the arcuate structure and a second stop structure at a second end of the arcuate structure extending outwardly from the arcuate structure.

18. The display mount system as claimed in claim 16, wherein the defined cross sectional shape is generally t-shaped.

19. The display mount system as claimed in claim 13, wherein the arcuate structure and the arcuate channel each have a radius of curvature and the radius of curvature is selected such that a center of the radius is positioned on an opposing side of the display interface from the supporting member interface and spaced apart from the display interface and near a center of gravity of the electronic flat panel display device.
